(19) United States
(12) Patent Application Publication
(10) Pub. No.: US 2025/0194428 A1
(43) Pub. Date: Jun. 12, 2025

(54) QUASI-TWO-DIMENSIONAL HALIDE PEROVSKITE THIN FILM AND PIEZOELECTRIC ENERGY HARVESTER COMPRISING THE SAME

(71) Applicant: UIF (University Industry Foundation), Yonsei University, Seoul (KR)

(72) Inventors: Yong Soo CHO, Seoul (KR); Kyeong Su JO, Seoul (KR); Da Bin KIM, Seoul (KR)

(73) Assignee: UIF (University Industry Foundation), Yonsei University, Seoul (KR)

(21) Appl. No.: 18/970,933

(22) Filed: Dec. 6, 2024

(30) Foreign Application Priority Data
Dec. 11, 2023 (KR) 10-2023-0179146

(51) Int. Cl. H10N 30/857; H10N 30/30; H10N 30/50

(52) U.S. Cl. CPC H10N 30/857; H10N 30/30; H10N 30/50

(57) ABSTRACT

The present invention relates to a quasi-two-dimensional halide perovskite thin film, in which the halide perovskite has the chemical formula X₂Aₙ₋₁BₙY₃ₙ₊₁, X is an organic material, A is at least one of methylammonium (MA), formamidinium (FA), and cesium (Cs), B is a metallic cation, Y is a halogen anion, n is a natural number greater than or equal to 2 and less than the natural number k, and as the value of n increases, the piezoelectricity increases.

### CROSS-REFERENCE TO RELATED APPLICATION

This application claims priority to and the benefit of Korean Patent Application No. 10-2023-0179146, filed on Dec. 11, 2023, the disclosure of which is incorporated herein by reference in its entirety.

### BACKGROUND

The present invention relates to a quasi-two-dimensional halide perovskite thin film, and a piezoelectric energy harvester including the same.

Energy harvesting refers to the technology of harvesting energy generated from natural energy sources such as solar light, vibration, heat, and wind power and converting it into electrical energy.

Such energy harvesting is attracting attention as an eco-friendly energy utilization technology that can maintain the stability, security, and sustainability of energy supply and reduce environmental pollution because it enables electrical energy to be obtained directly from nature.

An organo metallic halide perovskite (OMHPV) compound is a material with a structure represented by ABX₃, wherein A is an organic cation, B is a metallic cation such as Pb or Sn, X is a halogen anion, and B and X form an octahedron called BX₆. In addition, B is located at the center of the octahedron formed by X located at the corners, the octahedron forms a three-dimensional network with all corners connected to each other, and A is a material whose structure balances the charge of the entire network with large cations that fill the empty holes created by adjacent octahedra within the three-dimensional structure. The organic cations used in this material are mostly methylammonium cations (CH₃NH₃⁺, or MA⁺), but may also be formamidinium cations (HC(NH₂)₂⁺, or FA⁺). B is a divalent metal, such as Pb, Sn, or Cu.

Such OMHPV compounds have a wide range of applications due to their excellent electrical conductivity, excellent charge mobility, and excellent optical properties, and have various characteristics including long lifetime, high absorption wavelength spectra due to small energy band gaps, and wide charge-carrier diffusion lengths. In addition, these OMHPV compounds are attracting attention as promising materials for renewable energy applications because they have the advantages of being economical in material price, being able to be produced as solutions, having low production costs, and being able to be produced through low-temperature processes. In particular, research is underway on the use of these compounds as light absorbers for perovskite solar cells.

Meanwhile, research on the optical properties of quasi-two-dimensional halide perovskites, which have a different structure from the above-described three-dimensional halide perovskites and have a specific number (n) of inorganic material layers, is being reported. However, studies on the mechanical piezoelectricity of such a quasi-two-dimensional halide perovskite are insufficient.

### SUMMARY

The present invention is directed to controlling and improving the mechanical piezoelectricity of a quasi-two-dimensional halide perovskite.

According to an aspect of the present invention, the present invention provides a quasi-two-dimensional halide perovskite thin film, in which the halide perovskite has the chemical formula X₂Aₙ₋₁BₙY₃ₙ₊₁, X is an organic or inorganic material, A is at least one of methylammonium (MA), formamidinium (FA), and cesium (Cs), B is a metallic cation, Y is a halogen anion, n is a natural number greater than or equal to 2 and less than the natural number k, and as the value of n increases, the piezoelectricity increases.

According to another aspect of the present invention, the present invention provides a piezoelectric energy harvester, which includes the quasi-two-dimensional halide perovskite thin film.

According to the present invention, energy-efficient materials for the production of wearable pressure sensors can be developed by designing a novel two-dimensional piezoelectric composition-based energy harvesting device.

In addition, according to the present invention, the device of the present invention is free from environmental constraints due to its high moisture stability, unlike conventional three-dimensional halide-based devices.

In addition, according to the present invention, the development of wearable pressure sensors that meet market demands is possible based on controlled piezoelectric properties by controlling the number of layers of a quasi-two-dimensional halide perovskite.

### BRIEF DESCRIPTION OF THE DRAWINGS

FIG. 1 shows the crystal structure diagrams of spacer cations forming a quasi-two-dimensional halide perovskite thin film according to one embodiment of the present invention.

FIG. 2 shows a set of SEM images of the surfaces and cross-sections of quasi-two-dimensional halide perovskite thin films according to one embodiment of the present invention, which have HA as a spacer cation.

FIG. 3 shows a set of SEM images of the surfaces and cross-sections of quasi-two-dimensional halide perovskite thin films according to one embodiment of the present invention, which have BA as a spacer cation.

FIG. 4 shows a set of SEM images of the surfaces and cross-sections of quasi-two-dimensional halide perovskite thin films according to one embodiment of the present invention, which have PA as a spacer cation.

FIGS. 5 and 6 show the piezoelectricity of quasi-two-dimensional halide perovskite thin films according to one embodiment of the present invention.

FIG. 7 shows a schematic structural diagram and image of a piezoelectric energy harvester according to one embodiment of the present invention.

FIG. 8 shows the output voltages of piezoelectric energy harvesters according to one embodiment of the present invention.

FIG. 9 shows the output currents of piezoelectric energy harvesters according to one embodiment of the present invention.

FIG. 10 shows the maximum voltage and maximum current of piezoelectric energy harvesters according to one embodiment of the present invention.

FIGS. 11 and 12 show the enhanced performance of piezoelectric energy harvesters according to one embodiment of the present invention.

### DETAILED DESCRIPTION

The above objects, other objects, features and advantages of the present invention will be easily understood through the following exemplary embodiments relating to the accompanying drawings. The present invention is not limited to exemplary embodiments to be described below, but may be embodied in other forms. Rather, the embodiments presented herein are provided such that the technical idea can be fully conveyed to those of ordinary skill in the art.

In description of each drawing, like numerals denote like elements. In the accompanying drawings, the dimensions of structures are enlarged from the actual size for the clarity of the present invention. The terms “first” and “second” may be used to describe various components, but the components should not be limited by these terms. The terms are used only to distinguish one component from another component. For example, without departing from the scope of the present invention, a first component may be referred to as a second component, and similarly, a second component may also be referred to as a first component. Singular expressions include plural referents unless the context clearly indicates otherwise.

In the specification, it should be understood that the term “comprise,” “include,” or “have” is intended to indicate the presence of a characteristic, number, step, action, component or part described in the specification, or a combination thereof, but does not preclude the possibility of the presence or addition of one or more other characteristics, numbers, steps, actions, components, parts or a combination thereof. In addition, when apart of a layer, film, region or plate is disposed “on” another part, this includes not only a case in which the one part is disposed “directly on” the other part, but also a case in which a third part is interposed therebetween. In contrast, when a part of a layer, film, region or plate is disposed “under” another part, this includes not only a case in which the one part is disposed “directly under” the other part, but also a case in which a third part is interposed therebetween. In addition, in this application, “on” may include not only a case where something is disposed on an upper part of something else but also a case where something is disposed on a lower part of something else.

Unless otherwise specified, all numbers, values, and/or expressions that express components, reaction conditions, polymer compositions, and the amount of a mixture, used in the specification, are to be understood as being modified in all instances by the term “approximately” since these numbers are approximations that reflect the various uncertainties of measurement occurring to obtain these values, among other things. In addition, when a numerical range is disclosed in this description, such range is continuous and, unless indicated otherwise, includes all values from the minimum value to the maximum value. Furthermore, when such a range refers to an integer, unless otherwise indicated, all integers from the minimum value up to the maximum value are included.

According to one aspect of the present invention, as a quasi-two-dimensional halide perovskite thin film, a quasi-two-dimensional halide perovskite thin film in which the halide perovskite has the chemical formula X₂Aₙ₋₁BₙY₃ₙ₊₁ (n is a natural number greater than or equal to 2 and less than the natural number k) is provided. Here, X is an organic or inorganic material, A is at least one of methylammonium (MA), formamidinium (FA), and cesium (Cs), B is a metallic cation, and Y is a halogen anion.

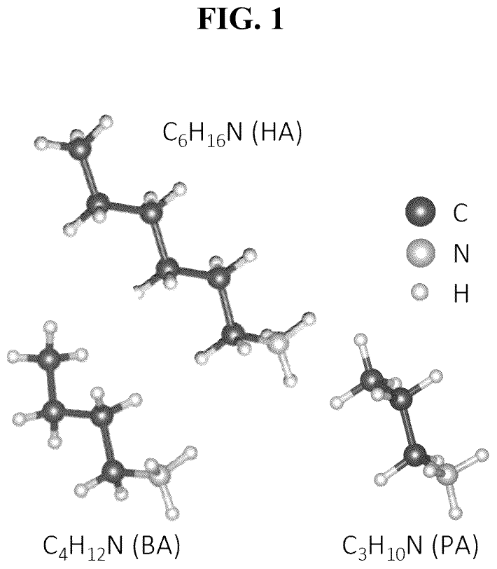

According to one embodiment of the present invention, X may include at least one of propylammonium (PA), butylammonium (BA), and hexylammonium (HA). Referring to FIG. 1, the crystal structure of X (spacer cation) can be seen.

According to one embodiment of the present invention, B may include at least one of Pb and Sn.

According to one embodiment of the present invention, Y may include at least one of I, Br, and Cl (halide anions).

According to one embodiment of the present invention, k may be any natural number from 5 to 10.

According to one embodiment of the present invention, as the value of n in the quasi-two-dimensional halide perovskite thin film increases, piezoelectricity may increase. For example, when k is 6, the piezoelectricity of the quasi-two-dimensional halide perovskite thin film may be increased from n=2 to n=5.

### EXPERIMENTAL EXAMPLES

The present invention will be described more specifically through the following experimental examples. The following experimental examples are merely examples to help understand the present invention, and the scope of the present invention is not limited thereto.

### A. Preparation of Quasi-Two-Dimensional Perovskite Thin Film

PA₂MAₙ₋₁PbₙI₃ₙ₊₁ (n=1 to 6) and MAPbI₃ precursor solutions were prepared by adding n-propyl ammonium iodide (PAI, Greatcell Solar Materials, Australia), methyl ammonium iodide (MAI, 99.9%, Greatcell Solar Materials, Australia), and lead iodide (PbI₂, 99.99%, TCI, Japan) in a mixed solvent (at a volume ratio of 7:3) of γ-butyrolactone (GBL, 99%, Sigma-Aldrich, USA) and dimethyl sulfoxide (DMSO, anhydrous, 99.9%, Sigma-Aldrich, USA) from a stoichiometric molar ratio based on the fixed concentration of PbI₂. Then, the solution was stirred at 70° C. for 5 hours.

Before deposition of the precursor solution, an indium tin oxide (ITO)-coated polyethylene terephthalate (PET) substrate (2.5 cm×2.5 cm) was sonicated in an isopropyl alcohol (IPA, C₃H₈O, anhydrous, Daejung, Korea) bath for 10 minutes and then surface-treated with O₂ (20 sccm) plasma at 100 W for 5 minutes. Subsequently, the prepared solution was spin-coated on ITO/PET at 1000 rpm for 10 seconds, coated at 4000 rpm for 30 seconds, and annealed at 100° C. for 15 minutes. Toluene (C₆H₅CH₃, 99.5%, Duksan, Korea) used as an antisolvent was dropped 10 seconds before spin coating was completed.

### 2. Preparation of Piezoelectric Energy Harvester

To produce a piezoelectric energy harvester, a 50 μm ITO/PEN substrate was coated with a PDMS (SYLGARD 184, Dow Corning, USA) solution consisting of a base monomer containing a 10 wt % curing agent through spin coating at 3000 rpm for 30 seconds, and then precured at 100° C. for 3 minutes. The precured PDMS layer was attached to a PA₂MAₙ₋₁PbₙI₃ₙ₊₁ film and cured again to ensure clean adhesion with no gap between them.

Afterward, the final structure of PEN/ITO/PDMS/PA₂MAₙ₋₁PbₙI₃ₙ₊₁/ITO/PET had Cu wires that were connected to both sides of the exposed ITO and sealed with a polyimide tape.

### 3. Measurement and Characterization

The surface and cross-sectional microstructures of the quasi-two-dimensional halide film were observed with a field emission scanning electron microscope (FE-SEM, JSM 7001F, JEOL, Japan), operating at an accelerating voltage of 75 kV. PL spectra were obtained at room temperature using a Raman spectrometer (LabRam Aramis, Horiba Jobin Yvon, France) with a 325 nm He—Cd laser source. The crystal structure of the quasi-two-dimensional halide film was examined using a high-resolution X-ray diffractometer (HR-XRD, SmartLab, Rigaku, Japan) irradiating Cu—Kα radiation (λ=1.5418 Å) in the 2θ range of 5 to 50°. The dielectric constant (εᵣ) was obtained as a function of frequency in the range of 10² to 10⁶ Hz using an impedance analyzer (HP 4194A, Hewlett Packard, USA).

The piezoelectric properties of the quasi-two-dimensional halide film were characterized by PFM (Nanoscope V Multimode, Bruker, USA) using conductive Pt/Ir-coated Si cantilever tips. The PR amplitude was measured by scanning the film surface (3 μm×3 μm) with a driving amplitude of 4 V in the lock-in mode at a variable AC voltage (Vac). The effective out-of-plane piezoelectric coefficient (d_{33,eff}) was estimated from the peak amplitude using the relationship A_{deflection}=d_{33,eff}×V_{ac}/16, where A_{deflection} is the peak amplitude. The P-E loop was obtained at a frequency of 100 Hz using the dynamic hysteresis method (DHM) based on a triangular pulse.

The harvesting performance was evaluated under cyclic bending at a frequency range of 0.6 to 3.0 Hz and bending strains of 0.6 to 3.0% using a single-axis high-speed fatigue machine (CTLM500, Ceratorq, Korea). The output performance was measured using a nanovoltmeter (Keithley 2182A, ValueTronics, USA) operated with an internal resistance of 10 MΩ, and the output current was determined using a galvanostat system (IviumStat, Ivium Technologies, Netherlands) operated with an internal resistance of 1 MΩ.

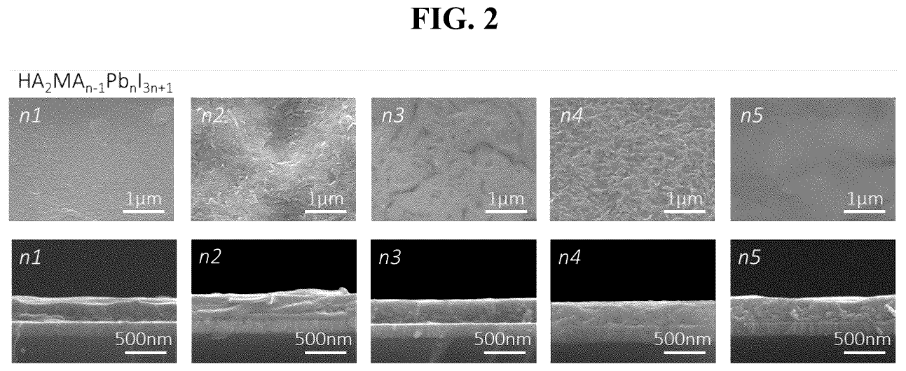

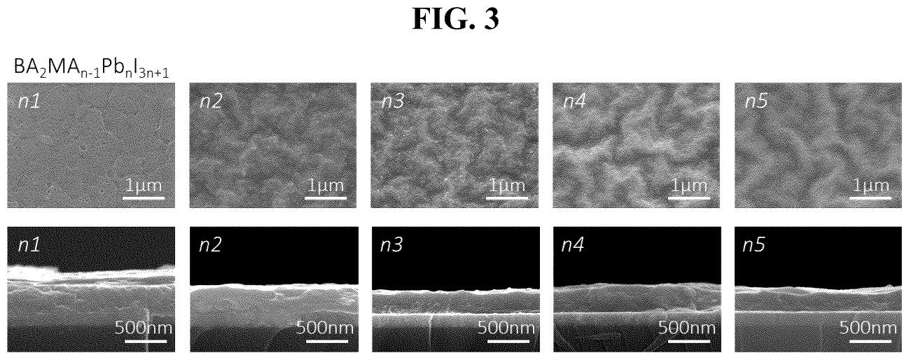

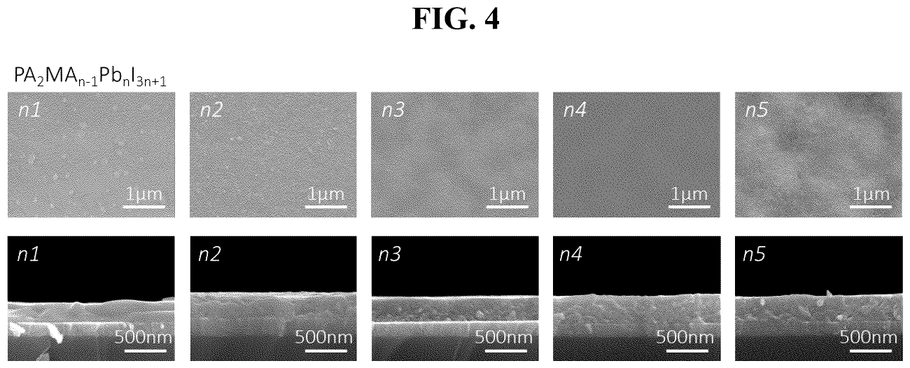

FIG. 2 shows a set of SEM images of the surfaces and cross-sections of quasi-two-dimensional halide perovskite thin films according to one embodiment of the present invention, which have HA as a spacer cation, FIG. 3 shows a set of SEM images of the surfaces and cross-sections of quasi-two-dimensional halide perovskite thin films according to one embodiment of the present invention, which have BA as a spacer cation, and FIG. 4 shows a set of SEM images of the surfaces and cross-sections of quasi-two-dimensional halide perovskite thin films according to one embodiment of the present invention, which have PA as a spacer cation.

Referring to FIGS. 2 to 4, it can be seen that the surface has a uniform and dense microstructure regardless of a chain length and n.

### 4. Piezoelectricity of Quasi-Two-Dimensional Halide Thin Film According to n

The n-dependent piezoelectricity of the quasi-two-dimensional halide thin film was examined using PFM.

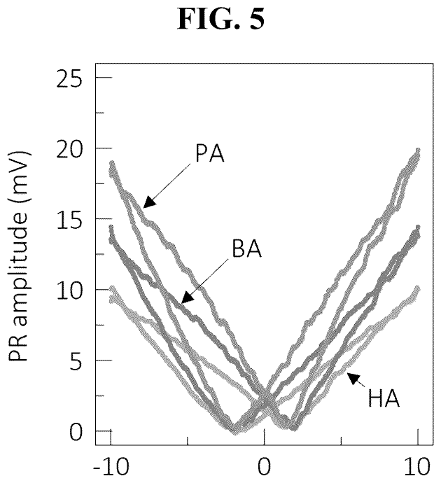

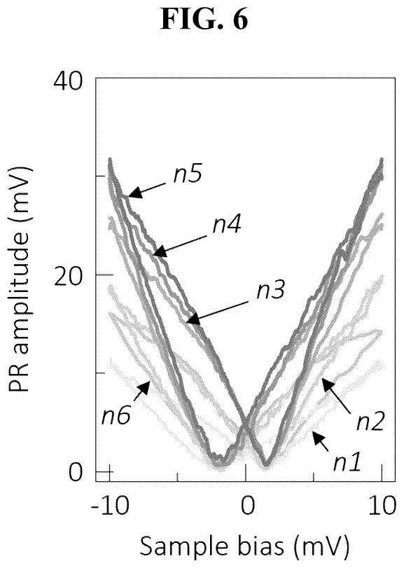

FIGS. 5 and 6 show the piezoelectricity of quasi-two-dimensional halide perovskite thin films according to one embodiment of the present invention.

Specifically, when n=2, FIG. 5 shows well-defined butterfly loops of the PFM amplitude signal with various DC biases applied from −10 V to +10 V for the thin films using HA, BA, and PA spacer cations. The PFM amplitudes were strongest on average in PA.

Table 1 below is a table analyzing the data shown in FIG. 1.

TABLE 1

| | HA | BA | PA |
|---|---|---|---|
| d_{33, eff} (pm V⁻¹) | 8.4 | 14.8 | 17.1 |

FIG. 6 shows well-defined butterfly loops of the PFM amplitude signal with various DC biases applied from −10 V to +10 V for the (PA)₂(MA)ₙ₋₁PbₙI₃ₙ₊₁ thin film. The PFM amplitude obtained the strongest value at n=5 according to the same trend as the amplitude-to-image.

Table 2 below is a table analyzing the data shown in FIG. 6. The n-dependent effective piezoelectric coefficient (d_{33,eff}) was calculated based on the PFM amplitude value of the peak for each film and these are compared in Table 2. As n increased, the obtained d_{33,eff} value increased up to the maximum value of 27.3 at n=5 and decreased to 19.1 at n=6 and 9.1 at n=∞(MAPbI₃).

TABLE 2

| n | 1 | 2 | 3 | 4 | 5 | 6 | MAPbI₃ (∞) |
|---|---|---|---|---|---|---|---|
| d₃₃ (pm/V) | 10.2 | 17.1 | 22.5 | 26.8 | 27.3 | 19.1 | 9.1 |

### 5. Evaluation of Performance of Piezoelectric Energy Harvester According to n

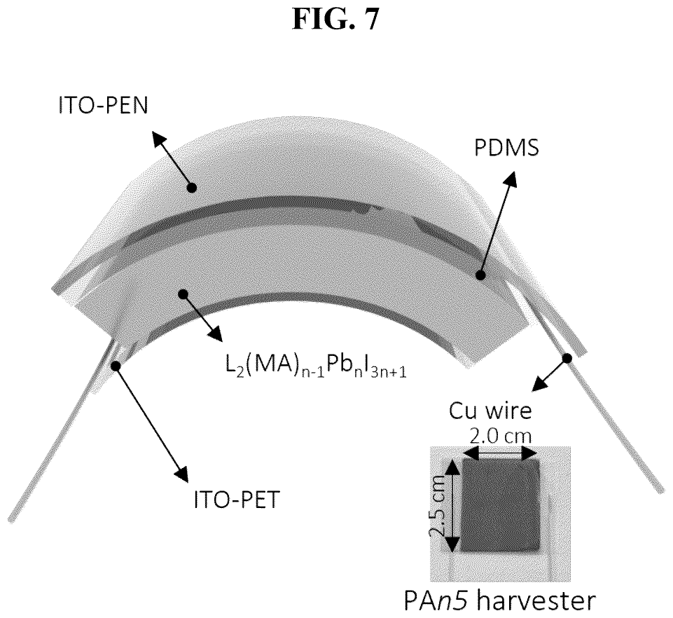

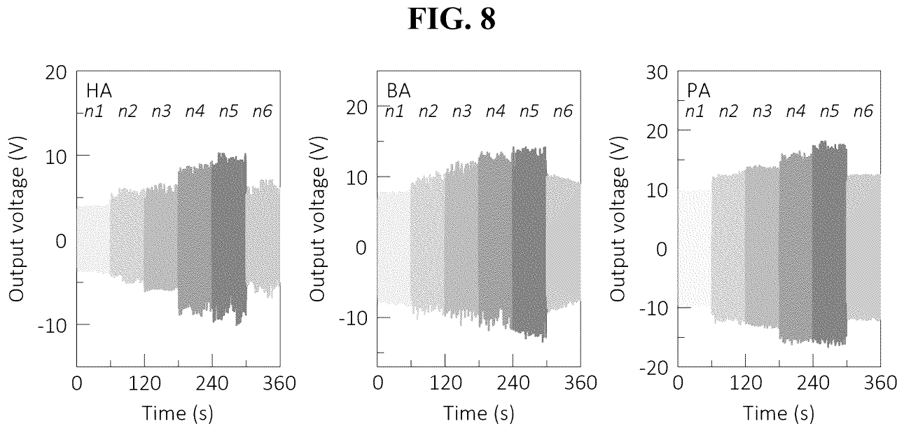

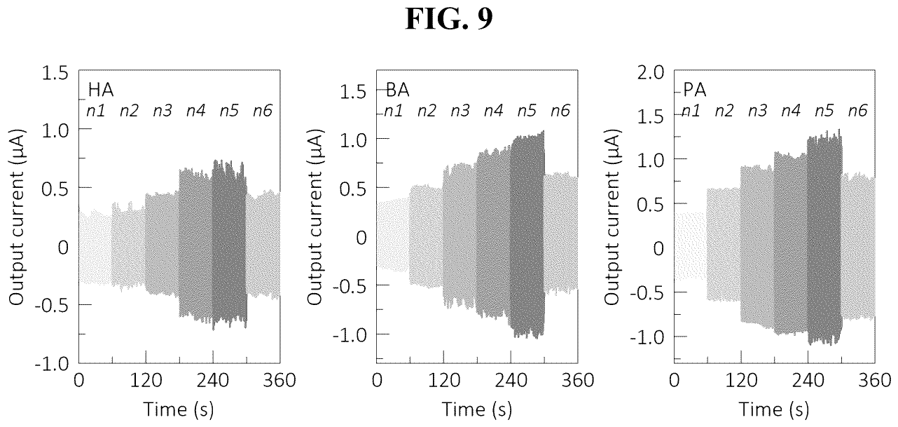

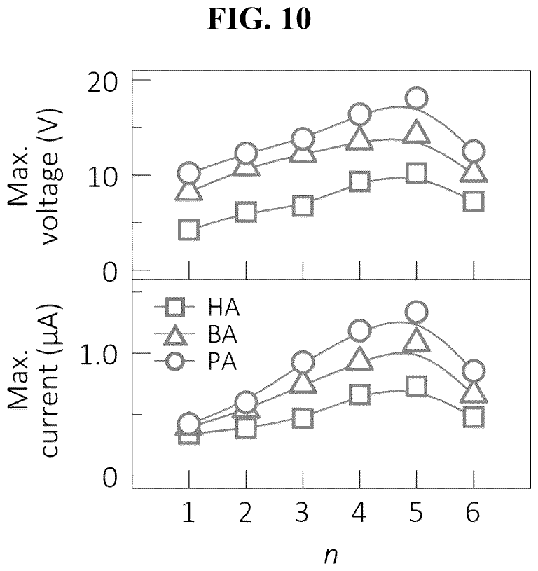

FIG. 7 shows a schematic structural diagram and image of a piezoelectric energy harvester according to one embodiment of the present invention. FIG. 8 shows the output voltages of piezoelectric energy harvesters according to one embodiment of the present invention. FIG. 9 shows the output currents of piezoelectric energy harvesters according to one embodiment of the present invention. FIG. 10 shows the maximum voltage and maximum current of piezoelectric energy harvesters according to one embodiment of the present invention.

Specifically, FIGS. 8 and 9 show the output voltages and output currents of thin film energy harvesters as various n functions at 3.0 Hz, respectively. Tables 3 and 4 below are tables analyzing the data shown in FIGS. 8 and 9.

TABLE 3

| | 1 | 2 | 3 | 4 | 5 | 6 | ∞ (MAPbI₃) |
|---|---|---|---|---|---|---|---|
| Max. voltage of | 10.2 | 12.3 | 13.8 | 16.4 | 18.1 | 12.5 | 6.5 |
| PA₂MAₙ₋₁PbₙI ₃ₙ₊₁ (V) | | | | | | | |
| Max. voltage of | 8.2 | 10.8 | 12.2 | 13.5 | 14.2 | 10.1 | 6.5 |
| BA₂MAₙ₋₁PbₙI₃ₙ₊₁ (V) | | | | | | | |
| Max. voltage of | 4.2 | 6.1 | 6.7 | 9.3 | 10.2 | 7.2 | 6.5 |
| HA₂MAₙ₋₁PbₙI₃ₙ₊₁ (V) | | | | | | | |

TABLE 4

| n | 1 | 2 | 3 | 4 | 5 | 6 | ∞ (MAPbI₃) |
|---|---|---|---|---|---|---|---|
| Max. current of | 425 | 600 | 928 | 1184 | 1334 | 855 | 316 |
| PA₂MAₙ₋₁PbₙI₃ₙ₊₁ (nA) | | | | | | | |
| Max. current of | 395 | 538 | 741 | 926 | 1080 | 661 | 316 |
| BA₂MAₙ₋₁PbₙI₃ₙ₊₁ (nA) | | | | | | | |
| Max. current of | 343 | 388 | 470 | 661 | 731 | 479 | 316 |
| HA₂MAₙ₋₁PbₙI₃ₙ₊₁ (nA) | | | | | | | |

Referring to FIGS. 8 and 9 and Tables 3 and 4, the change in performance of a piezoelectric energy harvester is evaluated as n (the number of octahedral layers between spacer cations) changes. As a result, it can be seen that the best characteristics are shown at n=5. Furthermore, it can be seen that the performance of the piezoelectric energy harvester according to one embodiment of the present invention is improved compared to three-dimensional MAPbI₃.

In addition, referring to FIG. 10, it can be seen that the maximum output voltage and the maximum output current according to FIGS. 8 and 9 change with n, and have the highest values at n=5.

### 6. Evaluation of Improved Performance of Piezoelectric Energy Harvester

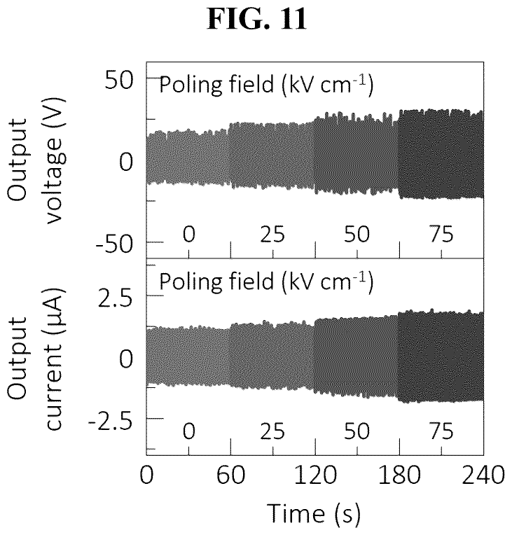

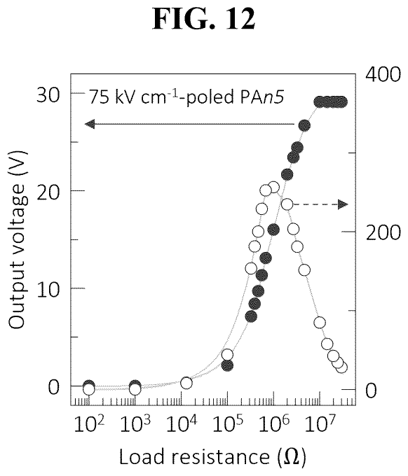

FIGS. 11 and 12 show the improved performance of piezoelectric energy harvesters according to one embodiment of the present invention. Specifically, FIG. 11 shows the output voltage and output current according to different poling fields measured at a bending frequency of 3.0 Hz and a bending strain of 0.60%. Table 3 below is a table analyzing the data shown in FIG. 11.

TABLE 5

| Poling field | 0 | 25 | 50 | 75 |
|---|---|---|---|---|
| Max Voltage (V) | 18.57 | 22.77 | 28.75 | 30.51 |
| Max current (nA) | 1184 | 1449 | 1654 | 1921 |

Referring to FIG. 11, when n=5 and performance is best, the performance of the piezoelectric energy harvester was further enhanced using an external electric poling method that applies an external electric field in advance for a certain period of time to the harvester.

FIG. 12 shows the change in output voltage and power for a 75 kV/cm-poled PA n5 harvester with increasing load resistance.

Referring to FIG. 12, it can be seen that the maximum power of 256 μW is obtained at 1 MΩ. As seen from FIG. 12, the optimal operating range that can maximize the device operating efficiency can be inferred according to the change in load resistance.

Although the present invention has been described above with reference to the preferred embodiments thereof, it will be understood by those of ordinary skill in the art that various modifications and changes may be made to the present invention without departing from the spirit and scope of the present invention as set forth in the claims below.

1. A quasi-two-dimensional halide perovskite thin film, in which the halide perovskite has the chemical formula X₂Aₙ₋₁BₙY₃ₙ₊₁,
X is an organic material, A is at least one of methylammonium (MA), formamidinium (FA), and cesium (Cs), B is a metallic cation, Y is a halogen anion, and n is a natural number greater than or equal to 2 and less than the natural number k, and
as the value of n increases, the piezoelectricity of the thin film increases.

2. The thin film of claim 1, wherein, as the value of n increases, the orientation of a spacer layer formed by X changes.

3. The thin film of claim 2, wherein, as the value of n increases, the orientation of a spacer layer formed by X changes from the horizontal direction to the vertical direction.

4. The thin film of claim 1, wherein k is any natural number from 5 to 10.

5. The thin film of claim 1, wherein X includes at least one of propylammonium (PA), butylammonium (BA), and hexylammonium (HA).

6. The thin film of claim 1, wherein B includes at least one of Pb and Sn.

7. The thin film of claim 1, wherein Y includes at least one of I, Br, and Cl.

8. The thin film of claim 5, wherein k is 6.

9. A piezoelectric energy harvester comprising the quasi-two-dimensional halide perovskite thin film of claim 1.

10. The piezoelectric energy harvester of claim 9, further comprising:
ITO/PET disposed on a side of the quasi-two-dimensional halide perovskite thin film;
PDMS disposed on the other side of the quasi-two-dimensional halide perovskite thin film; and
ITO/PEN disposed on a side opposite to one side of the PDMS on which the quasi-two-dimensional halide perovskite thin film is disposed.
